(19) United States
(12) Patent Application Publication
(10) Pub. No.: US 2021/0367169 A1
(43) Pub. Date: Nov. 25, 2021

(54) FLEXIBLE ORGANIC LIGHT EMITTING DIODE DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Kerong WU, Wuhan, Hubei (CN)

(21) Appl. No.: 16/337,100

(22) PCT Filed: Mar. 6, 2019
(86) PCT No.: PCT/CN2019/077209

§ 371 Date: Mar. 27, 2019

(30) Foreign Application Priority Data
Dec. 19, 2018 (CN) 201811557915.7

(51) Int. Cl. H01L 51/00; H01L 27/32

(52) U.S. Cl. CPC H01L 51/0097; H01L 27/3258; H01L 2251/5338; H01L 27/3274; H01L 27/3262

(57) ABSTRACT

Provided are a flexible organic light emitting diode display panel and a display device. The flexible organic light emitting diode display panel includes: a flexible substrate, including a non-bending area and a bending area; wherein a first thin film transistor is disposed on the non-bending area, and a second thin film transistor is disposed on the bending area; wherein the first thin film transistor is a low temperature polysilicon transistor, and the second thin film transistor is an organic thin film transistor.

### FIELD OF THE INVENTION

The present application relates to a display technology field, and more particularly to a flexible organic light emitting diode display panel and a display device.

### BACKGROUND OF THE INVENTION

With the development of display technology, the development and application of new generation display technologies are gradually applied to many fields, such as wearable devices, smart bracelets, smart watches, virtual reality (VR) devices and mobile phones for illustrations.

Compared with the conventional Thin Film Transistor Liquid Crystal Display (TFT-LCD), the biggest advantage of the Organic Light Emitting Diode (OLEO) is that the OLED can be made into a foldable product. Since the TFT portion contains many fragile film layers, the flexible foldable product may easily have structural or performance failure or even breakage during repeated folding.

Therefore, in a foldable OLED, a thin film transistor having a good bending property is generally used. However, thin film transistors having better bending properties possesses relatively lower mobility to inorganic thin film transistors, resulting in failure to provide sufficient gate driving current.

### SUMMARY OF THE INVENTION

The technical problem mainly solved by the present application is how to improve the bending resistance of the bending area, and to ensure that the non-bending area possesses sufficient gate driving current.

First, the present application provides a flexible organic light emitting diode display panel, including:

a flexible substrate, including a non-bending area and a bending area;

wherein a first thin film transistor is disposed on the non-bending area, and a second thin film transistor is disposed on the bending area;

wherein the first thin film transistor is a low temperature polysilicon transistor; and the second thin film transistor is an organic thin film transistor;

wherein the first thin film transistor includes:

a polysilicon layer, disposed on the flexible substrate;

a first insulating layer, a first gate layer, a second insulating layer and a third insulating layer, which are stacked and disposed on the polysilicon layer; and

a first via and a second via, which both penetrate the first insulating layer, the first gate layer, the second insulating layer and the third insulating layer and are respectively disposed on two sides of the polysilicon layer; wherein a first source is disposed in the first via, and a first drain is disposed in the second via, and the first source and the first drain cover at least a portion of the second insulating layer;

wherein a third thin film transistor is further disposed on the non-bending area and the bending area, and the third thin film transistor is an organic thin film transistor.

In the flexible organic light emitting diode display panel provided by the present application; the second thin film transistor includes:

a fourth insulating layer; a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the second polysilicon layer, and the second source and the second drain are electrically connected via the second polysilicon layer.

In the flexible organic light emitting diode display panel provided by the present application, an active layer of the first thin film transistor and an active layer of the second thin film transistor are disposed at different layers.

In the flexible organic light emitting diode display panel provided by the present application, the third thin film transistor includes:

a seventh insulating layer, a third gate layer, an eighth insulating layer, a fourth gate layer, a ninth insulating layer and a second organic semiconductor layer, which are stacked and disposed; wherein a third source and a third drain are oppositely disposed on the second organic semiconductor layer, and the third source and the third drain are electrically connected via the second organic semiconductor layer.

In the flexible organic light emitting diode display panel provided by the present application, the flexible OLED display panel further includes an organic planarization layer, an anode, a pixel defining layer and a spacer, which are stacked and disposed on the third source and the third drain, wherein the organic planarization layer covers the third source and the third drain.

In the flexible organic light emitting diode display panel provided by the present application, the second thin film transistor includes:

a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the first organic semiconductor layer, and the second source and the second drain are electrically connected via the first organic semiconductor layer.

In the flexible organic light emitting diode display panel provided by the present application, the first gate layer and the second gate layer are disposed at different layers.

Second, the present application provides a flexible organic light emitting diode display panel, including:

a flexible substrate, including a non-bending area and a bending area;

wherein a first thin film transistor is disposed on the non-bending area;

and a second thin film transistor is disposed on the bending area;

wherein the first thin film transistor is a low temperature polysilicon transistor, and the second thin film transistor is an organic thin film transistor.

In the flexible organic light emitting diode display panel provided by the present application, the first thin film transistor includes:

a polysilicon layer, disposed on the flexible substrate;

a first insulating layer, a first gate layer, a second insulating layer and a third insulating layer, which are stacked and disposed on the polysilicon layer; and

a first via and a second via, which both penetrate the first insulating layer, the first gate layer, the second insulating layer and the third insulating layer and are respectively disposed on two sides of the polysilicon layer; wherein a first source is disposed in the first via, and a first drain is disposed in the second via, and the first source and the first drain cover at least a portion of the second insulating layer.

In the flexible organic light emitting diode display panel provided by the present application, the second thin film transistor includes:

a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the second polysilicon layer, and the second source and the second drain are electrically connected via the second polysilicon layer.

In the flexible organic light emitting diode display panel provided by the present application, an active layer of the first thin film transistor and an active layer of the second thin film transistor are disposed at different layers.

In the flexible organic light emitting diode display panel provided by the present application, a third thin film transistor is further disposed on the non-bending area and the bending area, and the third thin film transistor is an organic thin film transistor.

In the flexible organic light emitting diode display panel provided by the present application, the third thin film transistor includes:

a seventh insulating layer, a third gate layer, an eighth insulating layer, a fourth gate layer, a ninth insulating layer and a second organic semiconductor layer, which are stacked and disposed; wherein a third source and a third drain are oppositely disposed on the second organic semiconductor layer, and the third source and the third drain are electrically connected via the second organic semiconductor layer.

In the flexible organic light emitting diode display panel provided by the present application, the flexible OLED display panel further includes an organic planarization layer, an anode, a pixel defining layer and a spacer, which are stacked and disposed on the third source and the third drain, wherein the organic planarization layer covers the third source and the third drain.

In the flexible organic light emitting diode display panel provided by the present application, the second thin film transistor includes:

a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the first organic semiconductor layer, and the second source and the second drain are electrically connected via the first organic semiconductor layer.

In the flexible organic light emitting diode display panel provided by the present application, the first gate layer and the second gate layer are disposed at different layers.

Third, the present application provides a display device, including a flexible organic light emitting diode display panel;

wherein the flexible organic light emitting diode display panel includes:

a flexible substrate, including a non-bending area and a bending area;

wherein a first thin film transistor is disposed on the non-bending area, and a second thin film transistor is disposed on the bending area;

wherein the first thin film transistor is a low temperature polysilicon transistor, and the second thin film transistor is an organic thin film transistor.

In the display device provided by the present application, the first thin film transistor includes:

a polysilicon layer, disposed on the flexible substrate;

a first insulating layer, a first gate layer, a second insulating layer and a third insulating layer, which are stacked and disposed on the polysilicon layer; and

a first via and a second via, which both penetrate the first insulating layer, the first gate layer, the second insulating layer and the third insulating layer and are respectively disposed on two sides of the polysilicon layer; wherein a first source is disposed in the first via, and a first drain is disposed in the second via, and the first source and the first drain cover at least a portion of the second insulating layer.

In the display device provided by the present application, the second thin film transistor includes:

a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the second polysilicon layer, and the second source and the second drain are electrically connected via the second polysilicon layer.

In the display device provided by the present application, the second thin film transistor includes:

a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the first organic semiconductor layer, and the second source and the second drain are electrically connected via the first organic semiconductor layer.

The beneficial effects of the present application are that the bending resistance of the bending area can be improved, and that the non-bending area possesses sufficient gate driving current.

### BRIEF DESCRIPTION OF THE DRAWINGS

In order to more clearly illustrate the embodiments of the present application, the following figures will be described in the embodiments are briefly introduced. It is obvious that the drawings are only some embodiments of the present application, those of ordinary skill in this field can obtain other figures according to these figures without paying the premise.

FIG. 1 is a structural diagram of the first embodiment of a flexible organic light emitting diode (OLED) display panel provided by the present application;

FIG. 2 is a flowchart of fabricating a first thin film transistor and a third thin film transistor on a non-bending area in the present application;

FIG. 3 is a flowchart of fabricating a second thin film transistor and a third thin film transistor on a bending area in the present application;

FIG. 4 is a structural diagram of the second embodiment of a flexible OLED display panel provided by the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments, Based on the embodiments of the present application, all other embodiments to those of skilled in the premise of no creative efforts obtained, should be considered within the scope of protection of the present application.

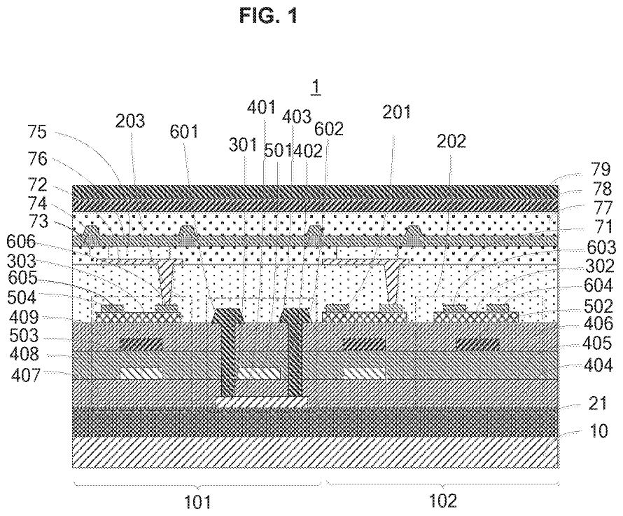

Please refer to FIG. 1. FIG. 1 is a sectional diagram of a flexible organic light emitting diode (OLED) display panel provided by the present application.

The present application provides a flexible OLED display panel 1 including: a flexible substrate 10 including a non-bending area 101 and a bending area 102. A buffer layer 21 is disposed on the flexible substrate 10. A first thin film transistor 201 is disposed on the non-bending area 101, and a second thin film transistor 202 is disposed on the bending area 102. The first thin film transistor 201 is a low temperature polysilicon transistor, and the second thin film transistor 202 is an organic thin film transistor.

For instance, a material of the flexible substrate 10 may be polyimide, and the flexible substrate 10 includes the non-bending area 101 and the bending area 102, The first thin film transistor 201 is disposed on the non-bending area 101, and the first thin film transistor 201 is a low temperature polysilicon transistor. The second thin film transistor 202 is disposed on the bending area 102, and the second thin film transistor 202 is an organic thin film transistor. The first thin film transistor 201 is disposed on the non-bending area 101, and the first thin film transistor 201 is used as a switching transistor of the non-bending area 101. By utilizing the property of the first thin film transistor 201 having high mobility and low sub threshold swing, it is possible to ensure that the non-bending area 101 possesses sufficient gate drive current. Meanwhile, the second thin film transistor 202 is disposed on the bending area 102, and the second thin film transistor 202 is used as a switching transistor of the bending area 102, By utilizing the high flexibility of the second thin film transistor 202, the bending area 102 is not easily broken as being bent, and thus the bending resistance of the bending area 102 is improved.

Please continue referring to FIG. 1. The first thin film transistor 201 may include: a polysilicon layer 301, disposed on the flexible substrate 10; a first insulating layer 401, a first gate layer 501, a second insulating layer 402 and a third insulating layer 403, which are stacked and disposed on the polysilicon layer 301; and

a first via 601 and a second via 602, which both penetrate the first insulating layer 401, the first gate layer 501, the second insulating layer 402 and the third insulating layer 403 and are respectively disposed on two sides of the polysilicon layer 301; wherein a first source 601 is disposed in the first via, and a first drain 602 is disposed in the second via, and the first source 601 and the first drain 602 cover at least a portion of the third insulating layer 403. Besides, the first thin film transistor 201 employs an inorganic thin film transistor, which can improve electron mobility and can ensure a sufficient gate driving current, and the first gate layer 501 and the polysilicon layer 301 form a capacitance.

The second thin film transistor 202 can includes: a fourth insulating layer 404, a fifth insulating layer 405, a second gate layer 502, a sixth insulating layer 406 and a first organic semiconductor layer 302, which are stacked and disposed. The sixth insulating layer 406 covers the second gate layer 302 and the fifth insulating layer 405, and a second source 603 and a second drain 604 are oppositely disposed on the second polysilicon layer 302, and the second source 603 and the second drain 604 are electrically connected via the first organic semiconductor layer 302.

The second thin film transistor 202 employs a bottom gate structure. Besides, the second thin film transistor 202 employs an organic thin film transistor to ensure good flexibility of the flexible OLED display panel, so that the flexible OLED display panel is not easily broken as being bent, thereby improving the product yield of the flexible OLED display panel.

A third thin film transistor 203 is further disposed on the non-bending area 101 and the bending area 102, and the third thin film transistor 203 is an organic thin film transistor.

The third thin film transistor 203 can includes: a seventh insulating layer 407, a third gate layer 503, an eighth insulating layer 408, a fourth gate layer 504, a ninth insulating layer 409 and a second organic semiconductor layer 303, which are stacked and disposed; wherein a third source 605 and a third drain 606 are oppositely disposed on the second organic semiconductor layer 303, and the third source 605 and the third drain 606 are electrically connected via the second organic semiconductor layer 303.

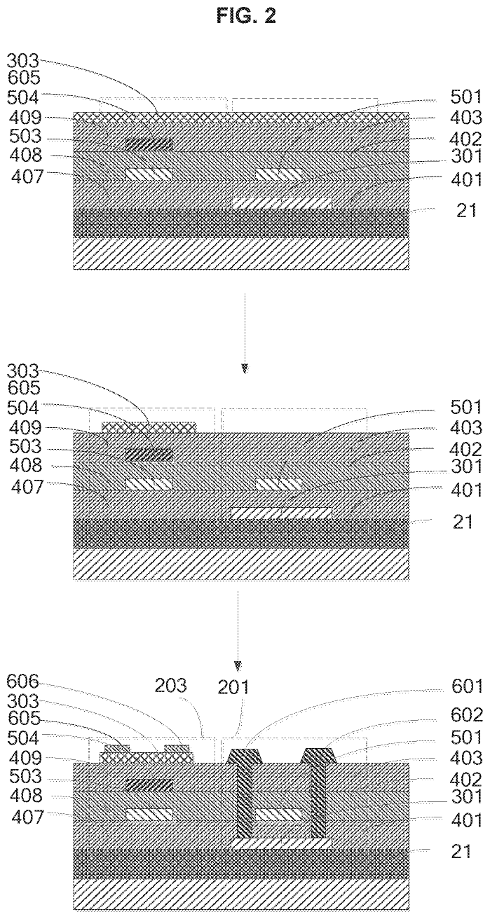

In the process, the first thin film transistor 201 and the second thin film transistor 203 can be fabricated together. Please refer to FIG. 2. FIG. 2 is a flowchart of fabricating a first thin film transistor and a third thin film transistor on a non-bending area in the present application.

First, a buffer layer 21 is formed on the non-bending area 101 on the flexible substrate 10. Then, a first insulating layer is formed on the buffer layer 21. Subsequently, the polysilicon layer 301 in the first thin film transistor 201 and the third gate layer 503 in the third thin film transistor 203 are formed on the first insulating layer. Then, the second insulating layer is formed on the polysilicon layer 301 and the third gate layer 503. The second insulating layer is disposed on the polysilicon layer 301 and the third gate layer 503, and covers the first insulating layer. Next, the fourth gate layer 504, the third insulating layer and an organic semiconductor layer are sequentially formed on the second insulating layer.

Specifically, after the organic semiconductor layer is formed, the organic semiconductor layer is etched to form the second organic semiconductor layer 303 of the third thin film transistor 203. Then, the source 601 and the drain 602 of the first thin film transistor 201 are fabricated.

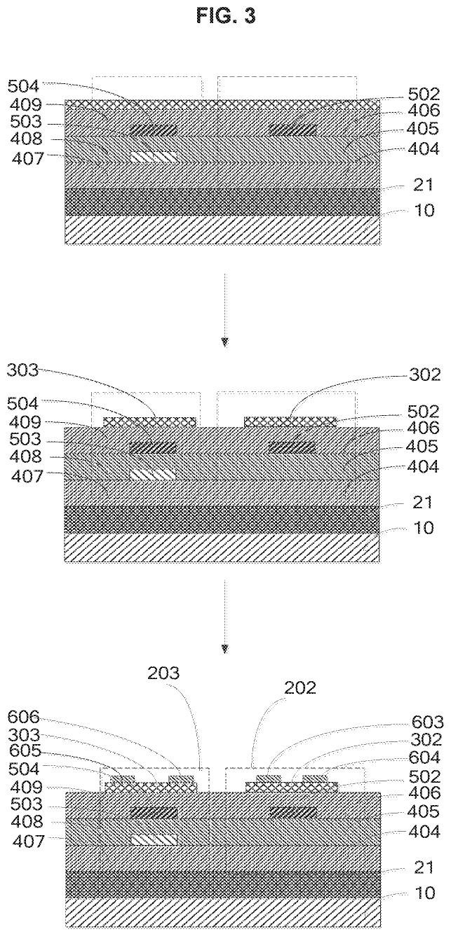

Besides, in the process, the second thin film transistor 202 and the second thin film transistor 203 can be fabricated together as shown in FIG. 3. FIG. 3 is a flowchart of fabricating the second thin film transistor and the third thin film transistor on the bending area in the present application.

First, a buffer layer 21 is formed on the bending area 102 on the flexible substrate 10. Then, a first insulating layer is formed on the buffer layer 21. Subsequently, the third gate layer 503 in the third thin film transistor 203 is formed on the first insulating layer. Then, the second insulating layer is formed on the third gate layer 503. The second insulating layer is disposed on the third gate layer 503, and covers the first insulating layer. Next, the second gate layer 502 of the second thin film transistor 202 and the fourth gate layer 504 of the third thin film transistor 203 are formed on the second insulating layer. Next, the third insulating layer and an organic semiconductor layer are sequentially formed on the second gate layer 502 and the fourth gate layer 504.

Specifically, after the organic semiconductor layer is formed, the organic semiconductor layer is etched to form the first organic semiconductor layer 302 of the second thin film transistor 202 and the second organic semiconductor layer 303 of the third thin film transistor 203.

In some embodiments, the panel further includes an organic planarization layer 71, an anode 72, a pixel defining layer 73, a spacer 74, an organic light emitting layer 75, a cathode 76, an encapsulation layer 77, a polarizing layer 78 and a touch layer 79, which are disposed on the third source 605 and the third drain 606. The organic planarization layer 71 covers the third source 605 and the third drain 606. Specifically, in this embodiment, the drain of the driving TFT, that is, the third drain 606 is electrically connected to the anode 72.

The first gate layer 501 is disposed at the same layer as the third gate layer 503.

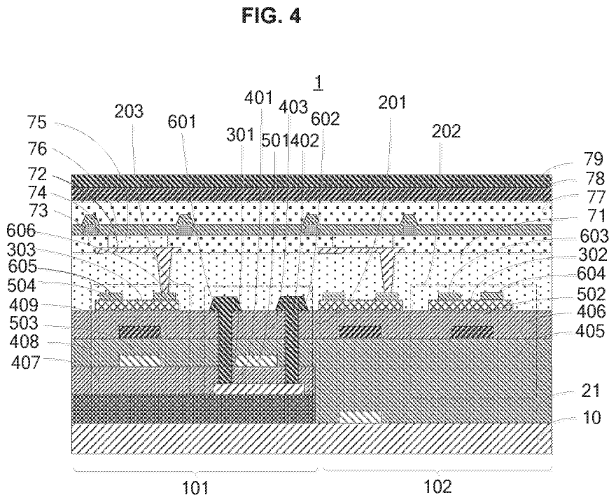

Please refer to FIG. 4. FIG. 4 is a structural diagram of the second embodiment of a flexible OLED display panel provided by the present application. The flexible OLED display panel 1 of FIG. 4 differs from the flexible OLED display panel of FIG. 1 in that the buffer layer 21 and the fourth insulating layer 404 of the bending area 102 have been etched during the fabricating process. Namely, the second thin film transistor 202 can include:

a fifth insulating layer 405, a second gate layer 502, a sixth insulating layer 406 and a first organic semiconductor layer 302, which are stacked and disposed; wherein the sixth insulating layer 406 covers the second gate layer 502 and the fifth insulating layer 405, and a second source 603 and a second drain 604 are oppositely disposed on the first organic semiconductor layer 302, and the second source 603 and the second drain 604 are electrically connected via the first organic semiconductor layer 302.

Specifically, in this embodiment, the difference from the previous embodiment is that the fourth insulating layer 404 is etched, thereby further improving the bending ability of the bending area 102. Besides, the structure of the driving transistor 203 is similar to that of the previous embodiment, and details are not described herein, again.

In some embodiments, the first gate layer 501 and the second gate layer 502 are disposed at different layers.

Correspondingly, the present application further provides a display device, including the flexible OLED display panel 1. For the structure of the flexible OLED display panel, refer to the previous embodiments, and details are not described herein, again.

The flexible organic light emitting diode display panel and the display device provided by the embodiments of the present application are described in detail. The principles and implementations of the present application are described in the specific examples. The description of the above embodiments is only for helping to understand the present application. Meanwhile, those skilled in the art will be able to change the specific embodiments and the scope of the application according to the idea of the present application. In conclusion, the content of the specification should not be construed as limiting the present application.

What is claimed is:

1. A flexible organic light emitting diode display panel, including:
a flexible substrate; including a non-bending area and a bending area;
wherein a first thin film transistor is disposed on the non-bending area, and a second thin film transistor is disposed on the bending area;
wherein the first thin film transistor is a low temperature polysilicon transistor; and the second thin film transistor is an organic thin film transistor;
wherein the first thin film transistor includes:
a polysilicon layer, disposed on the flexible substrate;
a first insulating layer, a first gate layer, a second insulating layer and a third insulating layer, which are stacked and disposed on the polysilicon layer; and
a first via and a second via, which both penetrate the first insulating layer, the first gate layer, the second insulating layer and the third insulating layer and are respectively disposed on two sides of the polysilicon layer; wherein a first source is disposed in the first via, and a first drain is disposed in the second via, and the first source and the first drain cover at least a portion of the second insulating layer;
wherein a third thin film transistor is further disposed on the non-bending area and the bending area, and the third thin film transistor is an organic thin film transistor.

2. The flexible organic light emitting diode display panel according to claim 1, wherein the second thin film transistor includes:
a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the second polysilicon layer, and the second source and the second drain are electrically connected via the second polysilicon layer.

3. The flexible organic light emitting diode display panel according to claim 1, wherein an active layer of the first thin film transistor and an active layer of the second thin film transistor are disposed at different layers.

4. The flexible organic light emitting diode display panel according to claim 1, wherein the third thin film transistor includes:
a seventh insulating layer, a third gate layer, an eighth insulating layer, a fourth gate layer, a ninth insulating layer and a second organic semiconductor layer, which are stacked and disposed; wherein a third source and a third drain are oppositely disposed on the second organic semiconductor layer, and the third source and the third drain are electrically connected via the second organic semiconductor layer.

5. The flexible organic light emitting diode display panel according to claim 4, further including an organic planarization layer, an anode, a pixel defining layer and a spacer, which are stacked and disposed on the third source and the third drain, wherein the organic planarization layer covers the third source and the third drain.

6. The flexible organic light emitting diode display panel according to claim 1, wherein the second thin film transistor includes:
a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the first organic semiconductor layer, and the second source and the second drain are electrically connected via the first organic semiconductor layer.

7. The flexible organic light emitting diode display panel according to claim 6, wherein the first gate layer and the second gate layer are disposed at different layers.

8. A flexible organic light emitting diode display panel, including;
a flexible substrate, including a non-bending area and a bending area;
wherein a first thin film transistor is disposed on the non-bending area, and a second thin film transistor is disposed on the bending area;
wherein the first thin film transistor is a low temperature polysilicon transistor, and the second thin film transistor is an organic thin film transistor.

9. The flexible organic light emitting diode display panel according to claim 8, wherein the first thin film transistor includes:
a polysilicon layer, disposed on the flexible substrate;
a first insulating layer, a first gate layer, a second insulating layer and a third insulating layer, which are stacked and disposed on the polysilicon layer; and
a first via and a second via, which both penetrate the first insulating layer, the first gate layer, the second insulating layer and the third insulating layer and are respectively disposed on two sides of the polysilicon layer; wherein a first source is disposed in the first via, and a first drain is disposed in the second via, and the first source and the first drain cover at least a portion of the second insulating layer.

10. The flexible organic light emitting diode display panel according to claim 8, wherein the second thin film transistor includes:
a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the second polysilicon layer, and the second source and the second drain are electrically connected via the second polysilicon layer.

11. The flexible organic light emitting diode display panel according to claim 8, wherein an active layer of the first thin film transistor and an active layer of the second thin film transistor are disposed at different layers.

12. The flexible organic light emitting diode display panel according to claim 8, wherein a third thin film transistor is further disposed on the non-bending area and the bending area, and the third thin film transistor is an organic thin film transistor.

13. The flexible organic light emitting diode display panel according to claim 12, wherein the third thin film transistor includes:
a seventh insulating layer, a third gate layer, an eighth insulating layer; a fourth gate layer, a ninth insulating layer and a second organic semiconductor layer, which are stacked and disposed; wherein a third source and a third drain are oppositely disposed on the second organic semiconductor layer, and the third source and the third drain are electrically connected via the second organic semiconductor layer.

14. The flexible organic light emitting diode display panel according to claim 13, further including an organic planarization layer, an anode, a pixel defining layer and a spacer, which are stacked and disposed on the third source and the third drain, wherein the organic planarization layer covers the third source and the third drain.

15. The flexible organic light emitting diode display panel according to claim 9, wherein the second thin film transistor includes:
a fourth insulating layer; a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the first organic semiconductor layer, and the second source and the second drain are electrically connected via the first organic semiconductor layer.

16. The flexible organic light emitting diode display panel according to claim 15, wherein the first gate layer and the second gate layer are disposed at different layers.

17. A display device, including a flexible organic light emitting diode display panel;
wherein the flexible organic light emitting diode display panel includes:
a flexible substrate, including a non-bending area and a bending area;
wherein a first thin film transistor is disposed on the non-bending area, and a second thin film transistor is disposed on the bending area;
wherein the first thin film transistor is a low temperature polysilicon transistor, and the second thin film transistor is an organic thin film transistor.

18. The display device according to claim 17, wherein the first thin film transistor includes:
a polysilicon layer, disposed on the flexible substrate;
a first insulating layer, a first gate layer, a second insulating layer and a third insulating layer, which are stacked and disposed on the polysilicon layer; and
a first via and a second via, which both penetrate the first insulating layer, the first gate layer, the second insulating layer and the third insulating layer and are respectively disposed on two sides of the polysilicon layer; wherein a first source is disposed in the first via, and a first drain is disposed in the second via, and the first source and the first drain cover at least a portion of the second insulating layer.

19. The display device according to claim 17, wherein the second thin film transistor includes:
a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the second polysilicon layer, and the second source and the second drain are electrically connected via the second polysilicon layer.

20. The display device according to claim 17, wherein the second thin film transistor includes:
a fourth insulating layer, a fifth insulating layer, a second gate layer, a sixth insulating layer and a first organic semiconductor layer, which are stacked and disposed; wherein the sixth insulating layer covers the second gate layer and the fifth insulating layer, and a second source and a second drain are oppositely disposed on the first organic semiconductor layer, and the second source and the second drain are electrically connected via the first organic semiconductor layer.
